(19) United States
(12) Patent Application Publication
(10) Pub. No.: US 2022/0301892 A1
(43) Pub. Date: Sep. 22, 2022

(54) WAFER CLEANING METHOD AND WAFER CLEANING APPARATUS

(71) Applicant: CHANGXIN MEMORY TECHNOLOGIES, INC., Hefei City (CN)

(72) Inventors: Shouzhuang Song, Hefei City (CN); Chang-Yi Tsai, Hefei City (CN); Lu-Yuan Lin, Hefei City (CN)

(21) Appl. No.: 17/457,799

(22) Filed: Dec. 6, 2021

Related U.S. Application Data
(63) Continuation of application No. PCT/CN2021/113075, filed on Aug. 17, 2021.

(30) Foreign Application Priority Data
Mar. 19, 2021 (CN) 202110294823.X

(51) Int. Cl. H01L 21/67; B08B 3/02; B08B 1/00; B24B 37/24

(52) U.S. Cl. CPC H01L 21/6704; B08B 3/024; B08B 1/002; B24B 37/24; B08B 1/007

(57) ABSTRACT

The present disclosure provides a method of cleaning a wafer and a wafer cleaning apparatus. The method of cleaning a wafer includes: providing a wafer to be cleaned, the surface of the wafer having contaminants; and spraying a surfactant onto the surface of the wafer, and scrubbing the surface of the wafer with a polishing pad to remove the contaminants from the surface of the wafer.

### CROSS-REFERENCE TO RELATED APPLICATIONS

This is a continuation of International Application No. PCT/CN2021/113075, filed on Aug. 17, 2021, which claims the priority to Chinese Patent Application 202110294823.X, titled “WAFER CLEANING METHOD AND WAFER CLEANING APPARATUS” and filed on Mar. 19, 2021. The entire contents of International Application No. PCT/CN2021/113075 and Chinese Patent Application 202110294823.X are incorporated herein by reference.

### TECHNICAL FIELD

The present disclosure relates to, but is not limited to, a wafer cleaning method and a wafer cleaning apparatus.

### BACKGROUND

Chemical Mechanical Polishing (CMP) is an important process step in the semiconductor manufacturing process. After the CMP process is completed, the polished wafer usually needs to be cleaned to remove polishing residues on the surface of the wafer. In the present cleaning process after polishing, a cleaning brush is usually used to scrub the surface of the wafer. When the cleaning brush completes the cleaning and separates from the wafer (at the moment when the cleaning brush is opened), due to the limitation of the structure of the cleaning brush itself, defect sources such as particles on the cleaning brush can easily adhere back to the surface of the wafer, to form sector-shaped or rod-shaped special pattern defects on the surface of the wafer. In addition, with the extension of the service life of the cleaning brush, the carrying capacity of the defect sources on the cleaning brush increases, so that the defect sources fall onto the surface of the wafer more easily at the moment when the cleaning brush is opened. The falling or back adhesion of the defect sources causes residues of contaminants on the surface of the wafer, reduces the wafer cleaning effect, and affects the smooth progress of subsequent semiconductor manufacturing processes.

### SUMMARY

The subject matter is described in detail herein below, which is not intended to limit the scope of protection of claims.

The present disclosure provides a method of cleaning a wafer and a wafer cleaning apparatus.

The first aspect of the present disclosure provides a method of cleaning a wafer, including:

providing a wafer to be cleaned, a surface of the wafer having contaminants; and

spraying a surfactant onto the surface of the wafer, and scrubbing the surface of the wafer with a polishing pad and removing the contaminants from the surface of the wafer.

The second aspect of the present disclosure provides a wafer cleaning apparatus, including:

a spraying module, configured to spray a surfactant to a wafer with contaminants on its surface; and

a scrubbing module, including a polishing pad, the polishing pad being configured to scrub the wafer by mechanical external force and remove the contaminants from the surface of the wafer.

### BRIEF DESCRIPTION OF THE DRAWINGS

The drawings, which are incorporated in and constitute a part of the specification, illustrate embodiments of the present disclosure and together with the description serve to explain the principles of the embodiments of the present disclosure. In these drawings, similar reference numerals are used for representing similar elements. The drawings in the following description are only some rather than all of the embodiments of the present disclosure. Those skilled in the art would be able to derive other drawings from these drawings without any creative efforts.

FIG. 1 is a flowchart of a method of cleaning a wafer in an embodiment of the present disclosure;

FIG. 2A is a schematic cross-sectional view of a wafer with contaminants according to an embodiment of the present disclosure;

FIG. 2B is a side view when the surface of the wafer is cleaned with a surfactant combined with polishing pad scrubbing in an embodiment of the present disclosure;

FIG. 2C is a schematic diagram when an oxide layer after chemical mechanical polishing is treated with the surfactant in an embodiment of the present disclosure;

FIG. 2D is a side view when the wafer is cleaned using an ultrasonic cleaning process in an embodiment of the present disclosure;

FIG. 2E is a side view when the wafer is rinsed with an acid cleaning agent in an embodiment of the present disclosure;

FIG. 2F is a side view when the wafer is rinsed with an alkaline cleaning agent in an embodiment of the present disclosure;

FIG. 3 is a structural block diagram of a wafer cleaning apparatus in an embodiment of the present disclosure.

### DETAILED DESCRIPTION

A clear and complete description will be made to the technical solutions in the embodiments of the present disclosure below in combination with the drawings in the embodiments of the present disclosure. Apparently, the embodiments described are part of the embodiments of the present disclosure, not all of them. All other embodiments obtained by those skilled in the art based on the embodiments of the present disclosure without any creative efforts shall fall within the protection scope of the present disclosure. It should be noted that the embodiments in the present disclosure and the features in the embodiments can be combined with each other on a non-conflict basis.

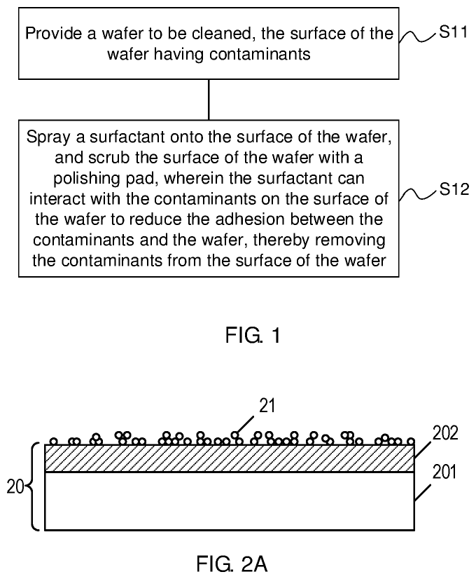

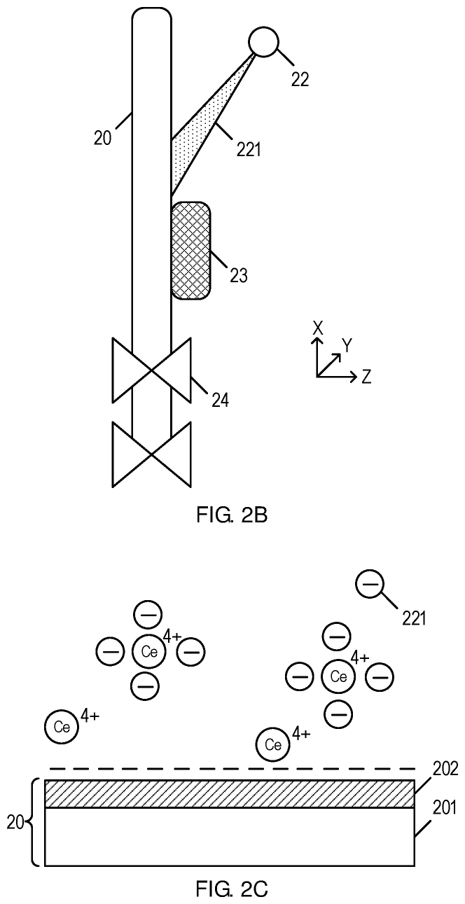

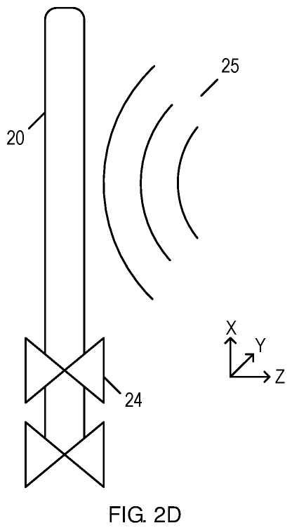

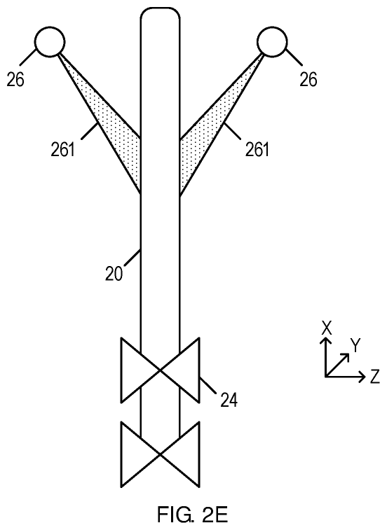

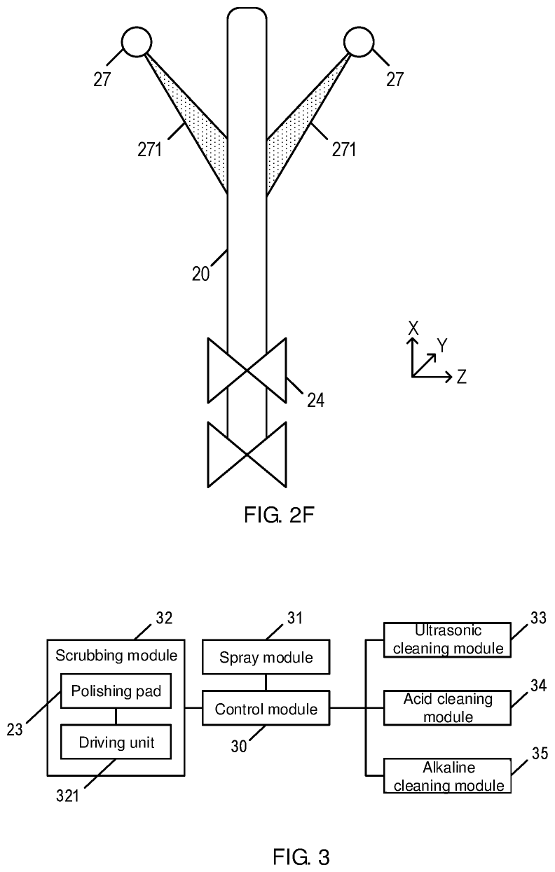

An embodiment of the present disclosure provides a method of cleaning a wafer. FIG. 1 is a flowchart of a method of cleaning a wafer in an embodiment of the present disclosure, and FIGS. 2A-2E are cross-sectional views of main processes during the cleaning of a wafer in the embodiment of the present disclosure. As shown in FIGS. 1 and 2A-2F, the method of cleaning a wafer provided in this embodiment includes:

Step S11, a wafer to be cleaned is provided, the surface of the wafer 20 having contaminants 21, as shown in FIG. 2A.

In an exemplary embodiment, the wafer 20 has undergone one or more process steps before cleaning, so that the contaminants 21 in the process steps remain on the surface of the wafer 20. For example, the wafer 20 includes a substrate 201 and an oxide layer 202 on the surface of the substrate 201. By chemical mechanical polishing on the oxide layer 202, the oxide layer 202 can be thinned and the surface of the oxide layer 202 can be flattened. After the chemical mechanical polishing process is completed, contaminants 21 remain on the surface of the oxide layer 202, the contaminants 21 including residual polishing liquid, debris generated in the chemical mechanical polishing process, etc.

Step S12, a surfactant is sprayed onto the surface of the wafer 20, and the surface of the wafer 20 is scrubbed with a polishing pad 23. The surfactant can interact with the contaminants 21 on the surface of the wafer 20 to reduce the adhesion between the contaminants 21 and the wafer 20, thereby removing the contaminants 21 from the surface of the wafer 20.

In this embodiment, the effect of reducing the adhesion between the contaminant 21 and the wafer 20 is achieved by means of the interaction between the surfactant serving as a cleaning agent and the contaminants 21, so that the contaminants 21 are more likely to drop from the surface of the wafer 20. The contaminants 21 are wiped from the surface of the wafer 20 in combination with the mechanical external force applied by the polishing pad 23 to the surface of the wafer 20, and the contaminants 21 can be separated from the wafer 20, so that most or even all of the contaminants 21 remaining on the surface of the wafer 20 in the front-end manufacturing process can be removed, to achieve the effect of removing the contaminants 21 from the surface of the wafer 20. Moreover, since the adhesion between the contaminants 21 and the wafer 20 is reduced, the contaminants 21 removed by the mechanical external force are difficult to adhere back to the surface of the wafer 20, which avoids secondary contamination of the wafer 20, improves the cleaning effect of the wafer 20, and ensures the continuous and stable progress of subsequent semiconductor manufacturing processes. In addition, the removal of the contaminants from the surface of the wafer by the mechanical external force of the polishing pad avoids the technical problem of surface defects caused by back adhesion of particles to the surface of the wafer due to the limitation of the structure of a cleaning brush when the surface of the wafer is scrubbed through the cleaning brush and the cleaning brush is separated from the wafer after the cleaning is completed in the prior art.

FIG. 2B is a side view when the surface of the wafer is cleaned with a surfactant combined with polishing pad scrubbing. In an exemplary embodiment, as shown in FIG. 2B, a surfactant 221 is sprayed onto the surface of the wafer 20 through a first spray pipe 22, so that the surfactant 221 covers the surface to be cleaned of the wafer 20. Meanwhile, the surface to be cleaned of the wafer 20 is scrubbed with a polishing pad 23, and the contaminants 21 are removed from the surface of the wafer 20 by friction.

In this embodiment, the polishing pad 23 is used to apply mechanical external force to the contaminants 21 on the surface of the wafer 20. The surface of the polishing pad 23 in contact with the wafer 20 is always the same plane on the polishing pad 23 (that is, the polishing surface of the polishing pad 23). Therefore, at the moment when the polishing pad 23 is separated from the wafer 20, the contaminants 21 will not adhere back from the polishing pad 23 to the surface of the wafer 20, which fundamentally avoids secondary contamination of the wafer 20. The polishing pad 23 has a plurality of protrusions on the polishing surface, and the protrusions are arranged in parallel in a direction parallel to the polishing surface. The contaminants 21 are removed from the surface of the wafer 20 by friction (i.e., mechanical external force) between the protrusions and the surface of the wafer 20.

In an exemplary embodiment, the interaction between the surfactant and the contaminants 21 on the surface of the wafer 20 is chemical or physical interaction. The specific form of interaction between the surfactant and the contaminants 21 depends on the type of the surfactant and the type of contaminants 21.

In an exemplary embodiment, the scrubbing the surface of the wafer 20 with a polishing pad 23 includes:

The wafer 20 and the polishing pad 23 are driven respectively to rotate, and the rotation directions of the wafer 20 and the polishing pad 23 are the same.

For example, as shown in FIG. 2B, when the wafer is scrubbed with the polishing pad 23, the wafer 20 is driven by a driving wheel 24 to rotate along a first axis, the first axis being parallel to the Z-axis direction and passing through the center of the wafer 20. The polishing pad 23 rotates along a second axis, the second axis being parallel to the Z-axis direction and passing through the center of the polishing pad 23, that is, the first axis being parallel to the second axis. The wafer 20 rotates clockwise along the first axis, and the polishing pad 23 rotates clockwise along the second axis; alternatively, the wafer 20 rotates counterclockwise along the first axis, and the polishing pad 23 rotates counterclockwise along the second axis. The wafer 20 and the polishing pad 23 rotate at different speeds.

In other embodiments, the scrubbing the surface of the wafer 20 with a polishing pad 23 includes: The wafer 20 is driven to rotate, and the polishing pad 23 is driven to reciprocate along a preset path on the surface of the wafer 20.

For example, as shown in FIG. 2B, when the wafer is scrubbed with the polishing pad 23, the wafer 20 is driven by a driving wheel 24 to rotate along a first axis, the first axis being parallel to the Z-axis direction and passing through the center of the wafer 20. The polishing pad 23 translates back and forth along a preset path on the surface of the wafer 20, that is, the polishing pad 23 swings back and forth along a preset path on the surface of the wafer 20.

In an exemplary embodiment, the wafer 20 includes a substrate 201 and an oxide layer 202 on the substrate 201, and the contaminants 21 are contaminants remaining after the oxide layer 202 undergoes a chemical mechanical polishing process; the scrubbing the wafer 20 with a surfactant combined with mechanical external force includes:

The oxide layer 202 is scrubbed with a surfactant combined with mechanical external force.

In an exemplary embodiment, the polishing liquid used in the chemical mechanical polishing process is cerium oxide, and the surfactant is sulfate or sulfonate.

Chemical mechanical polishing is a process that combines a chemical reaction process and a mechanical polishing process. During polishing, a polishing head applies a certain pressure on the back of the wafer, so that the front side of the wafer is close to the polishing pad. The polishing pad rotates by itself, and the polishing head drives the wafer and the polishing pad to rotate in the same direction, causing mechanical friction between the front side of the wafer and the surface of the polishing pad. During polishing, a certain thickness of film on the surface of the wafer is removed through a series of complex mechanical and chemical actions, so as to achieve the purpose of wafer planarization.

FIG. 2C is a schematic diagram when the oxide layer after chemical mechanical polishing is treated with the surfactant. For example, after the oxide layer 202 is polished with cerium oxide as a polishing liquid in the chemical mechanical polishing process, the surface of the oxide layer 202 is negatively charged, and the remaining cerium ions (Ce4+) are positively charged. The negatively charged sulfate or sulfonate is used as a surfactant 221, and the negatively charged surfactant 221 can chemically react with the positively charged cerium ions to reduce the adhesion of the cerium ions to the surface of the wafer 20. Subsequently, the polishing pad 23 applies mechanical external force to remove the remaining cerium oxide polishing liquid from the surface of the wafer 20.

The time for scrubbing the wafer 20 with a surfactant combined with mechanical external force may be adjusted according to different process requirements. For example, the scrubbing time may be controlled within a range of 30 s to 300 s.

In an exemplary embodiment, the surfactant has a mass concentration of less than 1%. The scrubbing with a surfactant combined with mechanical external force may be implemented at room temperature, for example, within a temperature range of 15° C. to 35° C.

In an exemplary embodiment, after scrubbing the wafer with a surfactant combined with mechanical external force, the method further includes:

The wafer 20 is cleaned using an ultrasonic cleaning process.

FIG. 2D is a side view when the wafer is cleaned using an ultrasonic cleaning process. The ultrasonic cleaning in this embodiment may be mega-frequency ultrasonic cleaning. The mega-frequency ultrasonic cleaning removes the contaminants 21 remaining on the surface of the wafer 20 by means of flow of bubbles generated by ultrasonic waves 25 on the surface of the wafer 20. The time for ultrasonic cleaning may be within a range of 30 s to 300 s. The ultrasonic cleaning solution may be TMAH (tetramethyl ammonium hydroxide) with a mass concentration of less than 1%, and the cleaning temperature ranges from 25° C. to 35° C. Alternatively, the ultrasonic cleaning solution is an SC1 (a mixture of ammonia, hydrogen peroxide and water) solution, and the cleaning temperature ranges from 20° C. to 80° C.

In an exemplary embodiment, after the wafer 20 is cleaned using an ultrasonic cleaning process, the method further includes:

The wafer 20 is rinsed with an acid cleaning agent.

In an exemplary embodiment, the rinsing the wafer 20 with an acid cleaning agent includes:

While the wafer 20 is driven to rotate, an acid cleaning agent is sprayed onto the surface of the wafer 20 to remove a natural oxide layer from the surface of the wafer.

FIG. 2E is a side view when the wafer 20 is rinsed with an acid cleaning agent. As shown in FIG. 2E, an acid cleaning agent 261 is sprayed onto the surface of the wafer 20 through second spray pipes 26, and the driving wheel 24 drives the wafer 20 to rotate in the XY plane (that is, rotate along an axis parallel to the Z axis and passing through the center of the wafer 20). The acid cleaning liquid has an etching effect on the natural oxide layer (such as a silicon dioxide layer generated by natural oxidation) formed on the surface of the wafer 20, which can etch away a thin natural oxide film on the surface of the wafer 20, thereby stripping off relatively stubborn particles in the contaminants 21. The natural oxide layer is different from the oxide layer 202 in the wafer 20. The natural oxide layer is formed on the surface of the oxide layer 202 by natural oxidation of contaminant particles on the surface of the wafer 20. The acid cleaning agent may be hydrofluoric acid with a mass concentration of 0.1% to 1%. Depending on the concentration of hydrofluoric acid used, the acid cleaning time should be controlled within a range of 5 s to 60 s, and the hydrofluoric acid is used at room temperature (15° C. to 35° C.). During the acid cleaning of the wafer 20, a cleaning brush is not required, and the natural oxide layer can be removed only by rinsing with the acid cleaning agent.

In an exemplary embodiment, after the wafer 20 is rinsed with an acid cleaning agent, the method further includes: The wafer 20 is rinsed with an alkaline cleaning agent.

In an exemplary embodiment, no cleaning brush is used when the wafer 20 is rinsed with an alkaline cleaning agent.

FIG. 2F is a side view when the wafer 20 is rinsed with an alkaline cleaning agent. As shown in FIG. 2F, an alkaline cleaning agent 271 is sprayed onto the surface of the wafer 20 through third spray pipes 27, and the driving wheel 24 drives the wafer 20 to rotate in the XY plane (that is, rotate along an axis parallel to the Z axis and passing through the center of the wafer 20). The alkaline cleaning agent 271 is mainly used to neutralize the remaining acid cleaning agent on the surface of the wafer 20 to avoid further erosion of the wafer 20 by the remaining acid cleaning agent and to restore the alkaline nature of the surface of the wafer 20. The time for alkaline cleaning may be controlled within a range of 30 s to 300 s. The alkaline cleaning agent may be TMAH (tetramethyl ammonium hydroxide) with a mass concentration of less than 0.1%, and the cleaning temperature is normal temperature. Alternatively, the alkaline cleaning agent may be an SC1 (a mixture of ammonia, hydrogen peroxide and water) solution, and the cleaning temperature ranges from 20° C. to 80° C.

In this embodiment, when the wafer 20 is cleaned with an alkaline cleaning agent, no cleaning brush is used, that is, the acid cleaning agent remaining on the surface of the wafer is removed only by means of the interaction between the alkaline cleaning agent and the acid cleaning agent remaining on the surface of the wafer 20 and the centrifugal force generated by the rotation of the wafer 20.

In addition, this embodiment further provides a wafer cleaning apparatus. FIG. 3 is a structural block diagram of a wafer cleaning apparatus in an embodiment of the present disclosure. The wafer cleaning apparatus provided in this embodiment may clean a wafer by using the method of cleaning a wafer shown in FIGS. 1 and 2A-2F. As shown in FIGS. 1, 2A-2F and 3, the wafer cleaning apparatus provided in this embodiment includes:

a spray module 31, configured to spray a surfactant onto a wafer 20 with contaminants 21 on its surface, wherein the surfactant can interact with the contaminants 21 on the surface of the wafer 20 to reduce the adhesion between the contaminants 21 and the wafer 20; and

a scrubbing module 32, including a polishing pad 23, wherein the polishing pad 23 is configured to scrub the wafer 20 by mechanical external force to remove the contaminants from the surface of the wafer 20.

In an exemplary embodiment, the interaction between the surfactant and the contaminants 21 on the surface of the wafer 20 is chemical or physical interaction.

In an exemplary embodiment, the wafer cleaning apparatus further includes:

a driving wheel 24, configured to carry the wafer 20 and drive the wafer 20 to rotate.

In an exemplary embodiment, the scrubbing module 32 further includes:

a driving unit 321, configured to drive the polishing pad 23 to rotate along its axis; or, configured to drive the polishing pad 23 to reciprocate along a preset path.

In an exemplary embodiment, the wafer cleaning apparatus further includes:

an ultrasonic cleaning module 33, configured to perform ultrasonic cleaning on the wafer 20.

In an exemplary embodiment, the wafer cleaning apparatus further includes:

an acid cleaning module 34, configured to rinse the wafer 20 with an acid cleaning agent.

In an exemplary embodiment, the wafer cleaning apparatus further includes:

an alkaline cleaning module 35, configured to rinse the wafer 20 with an alkaline cleaning agent.

The wafer cleaning apparatus may further be provided with a control module 30. The control module 30 is connected to the spray module 31, the scrubbing module 32, the ultrasonic cleaning module 33, the acid cleaning module 34 and the alkaline cleaning module 35, and is configured to adjust the working states (including an on state and an off state) of the spray module 31, the scrubbing module 32, the ultrasonic cleaning module 33, the acid cleaning module 34 and the alkaline cleaning module 35 connected to the control module 30, to ensure the smooth progress of the wafer cleaning process.

According to the method of cleaning a wafer and the wafer cleaning apparatus provided in this embodiment, the adhesion between the contaminants on the surface of the wafer and the wafer is reduced using a surfactant, so that the contaminants are more likely to fall off the surface of the wafer; then the contaminants are wiped from the surface of the wafer by means of mechanical external force applied by the polishing pad to the surface of the wafer, so that most or even all of the contaminants remaining on the surface of the wafer in the front-end process can be removed; and because the adhesion between the contaminants and the wafer is reduced, the probability that the contaminants adhere back to the surface of the wafer is reduced, which improves the wafer cleaning effect, reduces residues of the contaminants on the surface of the wafer, and ensures the smooth and stable progress of the semiconductor manufacturing process. In addition, the removal of the contaminants from the surface of the wafer by the mechanical external force of the polishing pad avoids the technical problem of surface defects caused by back adhesion of particles to the surface of the wafer due to the limitation of the structure of a cleaning brush when the surface of the wafer is scrubbed through the cleaning brush and the cleaning brush is separated from the wafer after the cleaning is completed in the prior art.

The embodiments or implementations in this specification are described in a progressive manner, each embodiment focuses on the differences from other embodiments, and the same or similar parts between the various embodiments may be referred to each other.

In the description of this specification, the descriptions with reference to the terms “embodiment”, “exemplary embodiment”, “some implementations”, “schematic implementation”, “example”, etc. mean that specific features, structures, materials or characteristics described in conjunction with the embodiments or examples are included in at least one embodiment or example of the present disclosure.

In this specification, the schematic descriptions of the above terms do not necessarily refer to the same embodiment or example. Moreover, the described specific features, structures, materials or characteristics may be combined in an appropriate manner in any one or more embodiments or examples.

In the description of the present disclosure, it should be noted that the orientations or positional relationships indicated by the terms “center”, “upper”, “lower”, “left”, “right”, “vertical”, “horizontal”, “inner”, “outer”, etc. are based on the orientations or positional relationships shown in the accompanying drawings, and are intended to facilitate the description of the present disclosure and simplify the description only, rather than indicating or implying that the device or element referred to must have a particular orientation or be constructed and operated in a particular orientation, and will not to be interpreted as limiting the present disclosure.

It can be understood that the terms “first”, “second”, etc. used in the present disclosure can be used in the present disclosure to describe various structures, but these structures are not limited by these terms. These terms are only used to distinguish the first structure from another structure.

In one or more drawings, the same elements are represented by similar reference numerals. For the sake of clarity, various parts in the drawings are not drawn to scale. In addition, some well-known parts may not be shown. For the sake of brevity, the structure obtained after several steps can be described in one figure. Many specific details of the present disclosure are described below, such as the structure, material, dimension, treatment process and technology of devices, in order to understand the present disclosure more clearly. However, as those skilled in the art can understand, the present disclosure may not be implemented according to these specific details.

Finally, it should be noted that the above embodiments are merely used to describe, but not to limit, the technical solutions of the present disclosure. Although the present disclosure is described in detail with reference to the above embodiments, those of ordinary skill in the art should understand that various modifications may be made to the technical solutions described in the foregoing embodiments, or equivalent substitutions may be made to some or all technical features thereof, and these modifications or substitutions do not make the essences of the corresponding technical solutions depart from the scope of the technical solutions of the embodiments of the present disclosure.

### INDUSTRIAL APPLICABILITY

According to the method of cleaning a wafer and the wafer cleaning apparatus provided by the embodiments of the present disclosure, the adhesion between the contaminants on the surface of the wafer and the wafer is reduced using a surfactant, so that the contaminants are more likely to fall off the surface of the wafer; then the contaminants are wiped from the surface of the wafer by means of mechanical external force applied by the polishing pad to the surface of the wafer, so that most or even all of the contaminants remaining on the surface of the wafer in the front-end process can be removed; and because the adhesion between the contaminants and the wafer is reduced, the probability that the contaminants adhere back to the surface of the wafer is reduced, which improves the wafer cleaning effect, reduces residues of the contaminants on the surface of the wafer, and ensures the smooth and stable progress of the semiconductor manufacturing process. In addition, the removal of the contaminants from the surface of the wafer by the mechanical external force of the polishing pad avoids the technical problem of surface defects caused by back adhesion of particles to the surface of the wafer due to the limitation of the structure of a cleaning brush when the surface of the wafer is scrubbed through the cleaning brush and the cleaning brush is separated from the wafer after the cleaning is completed in the prior art.

1. A method of cleaning a wafer, comprising:
providing a wafer to be cleaned, a surface of the wafer having contaminants; and
spraying a surfactant onto the surface of the wafer, and scrubbing the surface of the wafer with a polishing pad and removing the contaminants from the surface of the wafer.

2. The method of cleaning a wafer according to claim 1, wherein an interaction between the surfactant and the contaminants on the surface of the wafer is chemical interaction or physical interaction.

3. The method of cleaning a wafer according to claim 1, wherein the scrubbing the surface of the wafer with a polishing pad comprises:
driving, respectively, the wafer and the polishing pad to rotate, wherein rotation directions of the wafer and the polishing pad are the same.

4. The method of cleaning a wafer according to claim 1, wherein the scrubbing the surface of the wafer with a polishing pad comprises:
driving the wafer to rotate, and driving the polishing pad to reciprocate along a preset path on the surface of the wafer.

5. The method of cleaning a wafer according to claim 1, wherein the wafer comprises a substrate and an oxide layer on the substrate, and the contaminants are contaminants remaining after the oxide layer undergoes a chemical mechanical polishing process; scrubbing the wafer with a surfactant combined with mechanical external force comprises:
scrubbing the oxide layer with the surfactant combined with mechanical external force.

6. The method of cleaning a wafer according to claim 5, wherein a polishing liquid used in the chemical mechanical polishing process is cerium oxide, and the surfactant is sulfate or sulfonate.

7. The method of cleaning a wafer according to claim 6, wherein the surfactant has a mass concentration of less than 1%.

8. The method of cleaning a wafer according to claim 1, after scrubbing the wafer with a surfactant combined with mechanical external force, further comprising:
cleaning the wafer using an ultrasonic cleaning process.

9. The method of cleaning a wafer according to claim 8, after cleaning the wafer using an ultrasonic cleaning process, further comprising:
rinsing the wafer with an acid cleaning agent.

10. The method of cleaning a wafer according to claim 9, wherein the rinsing the wafer with an acid cleaning agent comprises:
while driving the wafer to rotate, spraying the acid cleaning agent onto the surface of the wafer to remove a natural oxide layer from the surface of the wafer.

11. The method of cleaning a wafer according to claim 9, after rinsing the wafer with an acid cleaning agent, further comprising:
rinsing the wafer with an alkaline cleaning agent.

12. The method of cleaning a wafer according to claim 11, wherein no cleaning brush is used when rinsing the wafer with the alkaline cleaning agent.

13. A wafer cleaning apparatus, comprising:
a spraying module, configured to spray a surfactant to a wafer with contaminants on a surface of the wafer; and
a scrubbing module, comprising a polishing pad, the polishing pad being configured to scrub the wafer by mechanical external force and remove the contaminants from the surface of the wafer.

14. The wafer cleaning apparatus according to claim 13, wherein an interaction between the surfactant and the contaminants on the surface of the wafer is chemical interaction or physical interaction.

15. The wafer cleaning apparatus according to claim 13, further comprising:
a driving wheel, configured to carry the wafer and drive the wafer to rotate.

16. The wafer cleaning apparatus according to claim 13, wherein, the scrubbing module further comprises:
a driving unit, configured to drive the polishing pad to rotate along an axis of the polishing pad; or, configured to drive the polishing pad to reciprocate along a preset path.

17. The wafer cleaning apparatus according to claim 13, further comprising:
an ultrasonic cleaning module, configured to perform ultrasonic cleaning on the wafer.

18. The wafer cleaning apparatus according to claim 13, further comprising:
an acid cleaning module, configured to rinse the wafer with an acid cleaning agent.

19. The wafer cleaning apparatus according to claim 13, further comprising:
an alkaline cleaning module, configured to rinse the wafer with an alkaline cleaning agent.
